(19) United States
(12) Patent Application Publication
(10) Pub. No.: US 2007/0035020 A1
(43) Pub. Date: Feb. 15, 2007

(54) Semiconductor Apparatus and Semiconductor Module

(75) Inventor: Mitsuo Umemoto, Gunma (JP)

Correspondence Address: FISH & RICHARDSON P.C., P.O. BOX 1022, MINNEAPOLIS, MN, 55440-1022, US

(73) Assignees: Sanyo Electric Co., Ltd., Moriguchi-shi (JP); Kanto Sanyo Semiconductors Co., Ltd., Oura-gun (JP)

(21) Appl. No.: 11/275,190

(22) Filed: Dec. 16, 2005

(30) Foreign Application Priority Data
Dec. 20, 2004 (JP) 2004-367523
Dec. 8, 2005 (JP) 2005-354656

(51) Int. Cl. H01L 23/48

(52) U.S. Cl. 257/737

(57) ABSTRACT

A semiconductor apparatus includes a semiconductor substrate, a through-electrode, a solder bump, and a circuit element. The semiconductor substrate has an electronic device formed on its front face. The through-electrode extends through the semiconductor substrate. The solder bump is disposed on the front side of the semiconductor substrate. The circuit element is disposed on the back side of the semiconductor substrate and is connected via the through-electrode to the electronic device.

### CROSS-REFERENCE TO RELATED APPLICATIONS

This application claims the benefit of priority from prior Japanese Patent Application Nos. 2004-367523 and 2005-354656, filed Dec. 20, 2004 and Dec. 8, 2005 in Japan, respectively, of which full contents are incorporated herein by reference.

### BACKGROUND OF THE INVENTION

1. Field of the Invention

The present invention relates generally to a semiconductor apparatus and a semiconductor module, and more particularly, to a technique for improving the mounting efficiency of the semiconductor apparatus.

2. Description of the Related Art

With the progress in downsizing and multi-functionalization of the hand-held equipments, the semiconductor apparatuses are facing a need to further improve their mounting efficiencies. For example, Japanese Patent Application Laid-open Publication No. H08-97375 discloses an integrated circuit (IC) such as GaAs MMIC capable of obtaining a desired capacitance value or a desired inductance value without increasing the chip size thereof.

In consideration of the influence on an electronic device, typical designing is made such that no circuit elements such as an inductor, a capacitance element and a resistance element are arranged on a surface (hereinafter, referred to as a front face) where the electronic device is formed of a semiconductor substrate making up the semiconductor apparatus. With the semiconductor apparatus being mounted on a circuit board of a subject equipment such as the hand-held equipment there exist substantially no or merely slight gaps between the semiconductor substrate and the circuit board, making it difficult to dispose the circuit element on top of a back face of the semiconductor substrate. Thus, to achieve the improved mounting efficiency of the semiconductor apparatus, consideration needs to be given to the influence on the electronic device and the status of mounting of the semiconductor apparatus onto the subject equipment.

### SUMMARY OF THE INVENTION

The present invention was conceived in view of such background, and one object of the present invention is to provide a semiconductor apparatus capable of improving the mounting efficiency thereof.

In order to achieve the above object, according to a main aspect of the present invention there is provided a semiconductor apparatus comprising a semiconductor substrate having a front face and a back face, the front face having an electronic device formed thereon; a through-electrode extending through the semiconductor substrate; a solder bump disposed on the front side of the semiconductor substrate, the solder bump connecting to the through-electrode; and a circuit element disposed on the back side of the semiconductor substrate, the circuit element connecting via the through-electrode to the electronic device.

According to the semiconductor apparatus of the present invention in this manner, the solder bump is formed on the front side of the semiconductor substrate. Mounting of this semiconductor apparatus onto a hand-held equipment, etc., is carried out face down, i.e., with its front side facing a circuit board. This enables the back side to be utilized as a space for mounting the circuit element, thereby improving the mounting efficiency of the semiconductor apparatus. Because of the circuit element being mounted on the back side, the electronic device is less affected by the circuit element.

In order to achieve the above object, according to a main aspect of the present invention there is provided a semiconductor apparatus comprising a semiconductor substrate having a front side and a back side, the front side having an electronic device formed thereon; an inductor formed on the back side of the semiconductor substrate; a through-electrode extending through the semiconductor substrate from a front face to a back face thereof, the through-electrode electrically connecting the electronic device and the inductor; and a conductive pattern formed at a position on the front side of the semiconductor substrate opposite to a position where the inductor is formed on the back side of the semiconductor substrate, the conductive pattern stabilizing inductance of the inductor.

Being formed “on the front face” of the semiconductor apparatus can include either being formed directly on the front face of the semiconductor substrate or being formed on the side of the front face of the semiconductor substrate relative to the center in the thickness direction of the semiconductor substrate.

According to this semiconductor apparatus, a major conductive substance capable of mutual inductance coupling with the inductor is a conductive pattern that is formed at a position opposite to the inductor with the semiconductor substrate interposed therebetween. Thus, by designing in advance the conductive pattern so that the inductor has a predetermined inductance characteristic in the separate semiconductor apparatus, the predetermined inductance characteristic of the inductor is kept as long as the semiconductor apparatus is mounted apart from the dielectric substance, etc. Stable keeping of the inductance enables the degree of possible interference of the inductor with the electronic device to be kept constant. Thus, according to this semiconductor apparatus, the mounting efficiency can be improved suppressing the interference of the inductor that may render the electronic device unstable.

In order to achieve the above object, according to a main aspect of the present invention there is provided a semiconductor apparatus comprising a semiconductor substrate having a front side and a back side, the front side having an electronic device formed thereon; an inductor formed on the back side of the semiconductor substrate; a through-electrode extending through the semiconductor substrate from a front face to a back face thereof, the through-electrode electrically connecting the electronic device and the inductor; and a conductive pattern formed via an insulating material at a position confronting a position where the inductor is formed on the back side of the semiconductor substrate, the conductive pattern stabilizing inductance of the inductor.

According to this semiconductor apparatus, a major conductive substance capable of mutual inductance coupling with the inductor is a conductive pattern that is formed confronting the inductor with the insulating material interposed therebetween. Thus, by designing in advance the conductive pattern so that the inductor has a predetermined inductance characteristic in the separate semiconductor apparatus, the predetermined inductance characteristic of the inductor is kept. According to this semiconductor apparatus, the semiconductor substrate acts to block magnetic lines of force from the front side toward the back side, whereas the conductive pattern serves to block magnetic lines of force from the back side toward the front side, so that the predetermined inductance characteristic of the inductor is kept. Stable keeping of the inductance enables the degree of possible interference of the inductor with the electronic device to be kept constant. Thus, according to this semiconductor apparatus, the mounting efficiency can be improved suppressing the interference of the inductor that may render the electronic device unstable.

In order to achieve the above object, according to a main aspect of the present invention there is provided a semiconductor module comprising a semiconductor apparatus and a mounting substrate mounted with the semiconductor apparatus, wherein the semiconductor apparatus includes a semiconductor substrate having a front side and a back side, the front side having an electronic device formed thereon; an inductor formed on the back side of the semiconductor substrate; and a through-electrode extending through the semiconductor substrate from a front face to a back face thereof, the through-electrode electrically connecting the electronic device and the inductor, and wherein the mounting substrate has thereon a conductive pattern formed at a position confronting a position where the inductor is formed on the back side of the semiconductor substrate, the conductive pattern stabilizing inductance of the inductor.

According to this semiconductor module, a major conductive substance capable of mutual inductance coupling with the inductor is a conductive pattern that is formed at a position confronting a position where the inductor is formed on a mounting board. Thus, by designing the conductive pattern on the mounting board so that the inductor has a predetermined inductance characteristic when the semiconductor apparatus is mounted on the mounting board, the predetermined inductance characteristic of the inductor is kept. According to this semiconductor module, the semiconductor substrate acts to block magnetic lines of force from the front side toward the back side, whereas the conductive pattern serves to block magnetic lines of force from the back side toward the front side, so that the predetermined inductance characteristic of the inductor is kept. Stable keeping of the inductance enables the degree of possible interference of the inductor with the electronic device to be kept constant. Thus, according to this semiconductor module, the mounting efficiency of the semiconductor apparatus can be improved suppressing the interference of the inductor that may render the electronic device unstable.

The present invention enables the semiconductor apparatus to have an improved mounting efficiency.

The above and other objects, aspects, features and advantages of the present invention will become more apparent from the accompanying drawings and following description of this specification.

### BRIEF DESCRIPTION OF THE DRAWINGS

For fuller understanding of the present invention and its advantages, reference should be made to the following description in conjunction with the accompanying drawings, in which:

FIG. 1 is a diagrammatic view in section of a semiconductor apparatus which will be described as an exemplary embodiment of the present invention;

FIG. 2A shows an example of the semiconductor apparatus having a circuit element configured by a back pattern itself, which will be described as the exemplary embodiment of the present invention;

FIG. 2B shows an example of the semiconductor apparatus having the circuit element configured by the back pattern itself, with a buffer layer interposed between a semiconductor substrate and the back pattern, which will be described as the exemplary embodiment of the present invention;

FIGS. 3A to 3H illustrate the process of forming a through-electrode in the semiconductor substrate, which will be described as the exemplary embodiment of the present invention;

FIG. 4 is a process flow for forming a back pattern, which will be described as the exemplary embodiment of the present invention;

FIG. 5 is a process flow for forming a front pattern, which will be described as the exemplary embodiment of the present invention;

FIG. 6 is a diagrammatic view in section of another semiconductor apparatus which will be described as another exemplary embodiment of the present invention;

FIGS. 7A and 7B are diagrammatic views in section of the another semiconductor apparatus that is mounted on a circuit board, which will be described as another exemplary embodiment of the present invention;

FIG. 8 shows diagrammatically the section of a further semiconductor apparatus which will be described as another exemplary embodiment of the present invention;

FIG. 9 shows diagrammatically the section of a semiconductor module which will be described as another exemplary embodiment of the present invention; and

FIGS. 10A to 10H illustrate another process of forming the through-electrode in a semiconductor substrate, which will be described as the another exemplary embodiment of the present invention.

### DETAILED DESCRIPTION OF THE INVENTION

At least the following matters will become apparent from the descriptions of this specification and of the accompanying drawings.

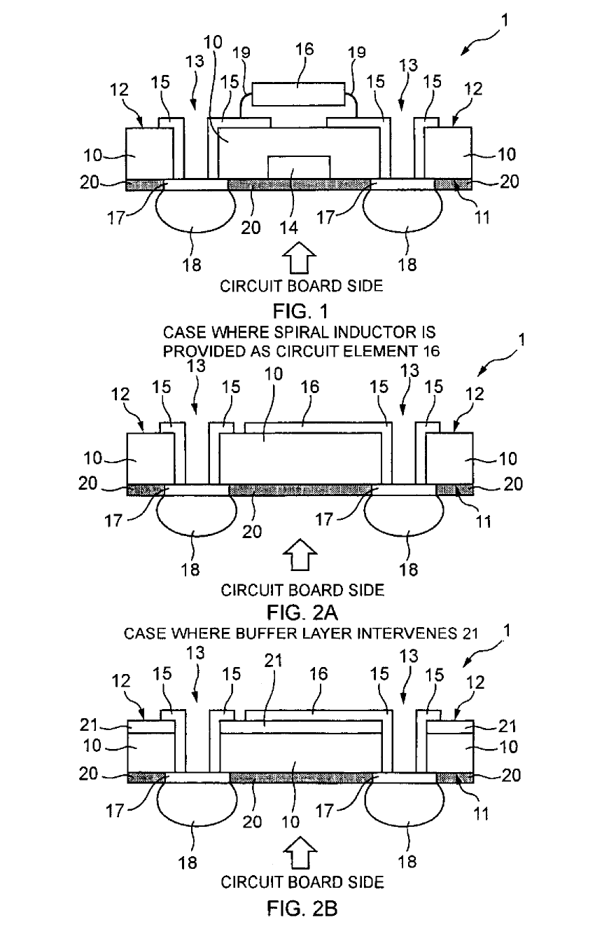

FIG. 1 shows in diagrammatic section a semiconductor apparatus generally designated at 1 that will now be described as an exemplary embodiment of the present invention. At predetermined locations on a semiconductor substrate 10 made of silicon (Si) are formed through-electrodes 13 extending from a front face 11 to a back face 12 of the semiconductor substrate 10 therethrough. On the front face 11 of the semiconductor substrate 10 is formed an electronic device 14 such as an integrated circuit or a CMOS (Complementary Metal Oxide Semiconductor), linear (bipolar), BiCMOS, MOS or discrete element. The electronic device 14 is formed e.g., by subjecting the semiconductor substrate 10 to various pre-treatments such as thermal oxidation method, CVD (Chemical Vapor Deposition), sputtering, lithography and impurity diffusion.

A wiring pattern (hereinafter, referred to as a “back pattern 15”) is formed on the portions where the through-electrodes 13 lie of the back face 12 of the semiconductor substrate 10. If the semiconductor substrate 10 is grounded, then the back pattern 15 needs to be electrically insulated from the semiconductor substrate 10, so that the back pattern 15 is formed via, e.g., silicon oxide (SiO₂) film or insulating resin on top of the semiconductor substrate 10. On the contrary, if the semiconductor substrate 10 functions as a collector electrode with the back pattern 15 electrically connected to the collector electrode, the back pattern 15 becomes equal in potential to the semiconductor substrate 10, rendering the insulating treatment unnecessary. The material of the back pattern 15 can be e.g., copper, gold, silver, tin, indium, aluminum, nickel, chrome or alloys thereof. On top of the back face 12 of the semiconductor substrate 10 is disposed a circuit element 16 (e.g., a passive element such as a resistor, an inductor or a capacitor) connecting to the back pattern 15. The circuit element 16 is connected via wire bonding 19 to predetermined locations on the back pattern 15. Instead of the wire bonding 19, the circuit element 16 may be firmly secured or connected to the back pattern 15 by means of conductive pasting or soldering.

A wiring pattern (hereinafter, referred to as a “front pattern 17”) acting as a bonding pad for the electronic device 14 is formed on the portions where the through-electrodes 13 lie on the front face 11 of the semiconductor substrate 10. The material of the front pattern 17 can be e.g., copper, gold, silver, tin, indium, aluminum, nickel, chrome or alloys thereof. Solder resist 20 is applied to portions other than the portions acting as the bonding pad on the front face 11 of the semiconductor substrate 10. Solder bumps 18 are formed on the portions of the front pattern 17 acting as the bonding pad. Although the front pattern 17 is shown formed directly on the semiconductor substrate 10 of silicon (Si) so as to be in direct contact with so-called active regions for the sake of simplicity of the drawing, the front pattern 17 in fact is formed via at least one layer of insulating film on top of the active regions needing electrical insulation.

When the thus configured semiconductor apparatus 1 is intended to be mounted on a circuit board of a hand-held equipment for example, the semiconductor apparatus 1 is face-down mounted such that the front face 11 of the semiconductor substrate 10 having the electronic device 14 (and the solder bumps 18) formed thereon confronts the circuit board of the hand-held equipment. In the semiconductor apparatus 1 of this embodiment, the circuit element 16 connecting to the electronic device 14 is disposed on top of the back face 12 of the semiconductor substrate 1 by way of the through-electrodes 13 whereas the solder bumps 18 are disposed on the front face 11 thereof, thus securing a space for mounting the circuit element 16 on top of the back face 12 of the semiconductor 10. For this reason, the semiconductor apparatus 1 of this embodiment enables the space on top of the back face 12 of the semiconductor substrate 10 to effectively be utilized. This results in downsizing of the semiconductor apparatus 10. It also becomes possible to mount a large-sized circuit element 16 that has hitherto been difficult to mount, thereby increasing the degree of freedom in designing.

Due to the circuit element 16 mounted on top of the back face 12, the semiconductor apparatus 1 of the embodiment allows the circuit element 16 to exert less influence on the electronic device 14 as compared with the case where the circuit element 16 is mounted on top of the front face 11. This enables the passive element such as the inductor or the capacitor that may otherwise affect peripheral circuits to be disposed as the circuit element 16 on the semiconductor apparatus 1. It is to be noted that the circuit element 16 may be an external component operating independently of the semiconductor apparatus 1 or may be a mounted component operating in conjunction with the semiconductor apparatus 1.

The circuit element 16 is not limited to such an element like a chip element that is configured independent of the back pattern 15. For example, the circuit element 16 may be configured by the back pattern 15 itself. FIG. 2A shows an example where a spiral inductor (planar coil) is provided as the circuit element 16 configured by the back pattern 15 itself. In case of a thin semiconductor substrate 10, characteristics of the circuit element 16 may possibly change due to a deformation of the semiconductor substrate 10. Therefore, as shown in FIG. 2B for example, a buffer layer 21 may intervene between the semiconductor substrate 10 and the back pattern 15. In this case, the buffer layer 21 is disposed on the back face 12 of the semiconductor substrate 10 so that the electronic device 14 is less influenced. The material of the buffer layer 21 can thus be diverse. For the purpose of improving Q value, for example, the material of the buffer layer 21 can be one having a small specific resistance such as pure silicon (Si). To improve the high-frequency characteristics, the material may be one with a low dielectric constant. With a view of relieving the stress, the buffer layer 21 may be a resin sheet, etc.

Description will then be made of a method of fabricating the semiconductor apparatus 1 configured as set forth hereinabove. In the description that follows, the semiconductor substrate 10 is a silicon substrate. The base wafer is a 130 μm thick silicon wafer having, on its front face 11 and back face 12, 5 μm thick insulating layers 155 and 156, respectively, of silicon oxide film (SiO₂) applied by thermal oxidation method, plasma CVD (Chemical Vapor Deposition), sputtering, etc. The front face of the semiconductor substrate 10 has thereon an electronic device such as an active element or integrated circuit of MOS (Metal Oxide Semiconductor) structure or of BIP (Bipolar) structure, formed by a pre-step such as thermal oxidation method, CVD (Chemical Vapor Deposition), sputtering, lithography or impurity diffusion.

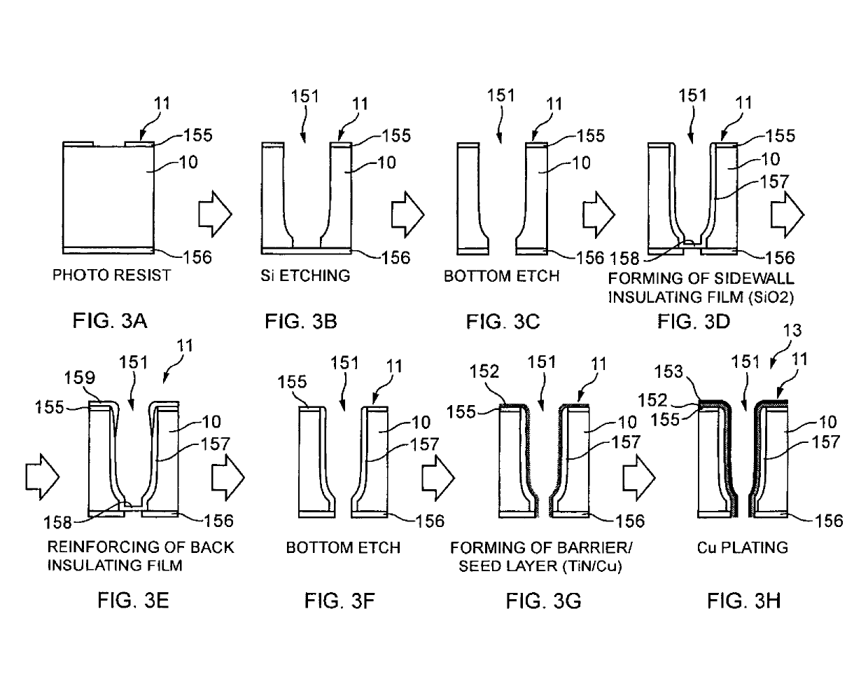

FIGS. 3A to 3H show the steps of forming the through-electrode 13 in the semiconductor substrate 10. To form the through-electrode 13, photo resist is applied to portions other than a portion (40 μm dia.) where the through-electrode 13 is to be formed, after which etching is performed using an etching gas such as carbon tetrafluoride (CF₄) to remove the insulating layer 155 lying on the portion where the through-electrode 13 is to be formed. FIG. 3A shows the status after the removal of the insulating layer 155 lying on the portion where the through-electrode is to be formed.

Etching is then performed using an etching gas such as carbon hexafluoride (CF₆) to form a through-hole 151 in the semiconductor substrate 10 (FIG. 3B). As a result of this, the insulating layer 156 is exposed at the bottom of the through-hole 151. Etching is then performed using an etching gas such as carbon tetrafluoride (CF₄) to remove the portion of the insulating layer 156 exposed at the bottom of the through-hole 151 (FIG. 3C).

To insulate a silicon surface exposed on an inner peripheral surface of the through-hole 151, an SiO₂ insulating film 157 is then formed on the inner peripheral surface by CVD, thermal oxidation method, sputtering, etc (FIG. 3D). It is to be noted that execution of this step allows SiO₂ 158 to again adhere to the bottom of the through-hole 151.

SiO₂ 158 adhering to the bottom of the through-hole 151 is then removed. At that time, to prevent the insulating film 157 of the through-hole 151 in the vicinity of the front face 11 from peeling off, a protection film 159 is formed in advance on the portions of the through-hole 151 near the front face 11 by CVD, thermal oxidation method, sputtering, etc (FIG. 3E). After the formation of the protection film 159, etch back is performed from the front face 11. This removes SiO₂ 158 formed at the bottom of the through-hole 151. FIG. 3F shows the status of the above steps, the through-electrode 13 is formed in the semiconductor substrate 10.

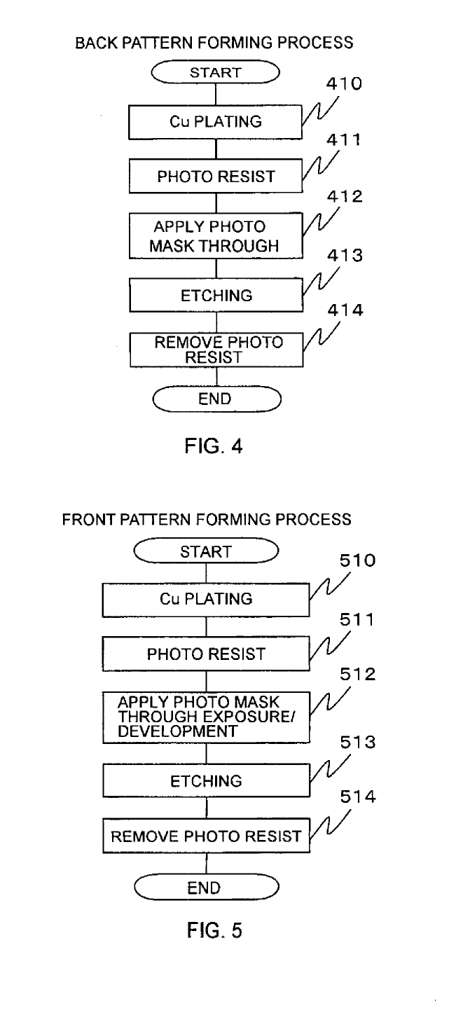

The back pattern 15 is then formed on the back face 12 of the semiconductor substrate 10 having the through-electrode 13 thus formed therein. FIG. 4 shows a process flow when the back pattern 15 is formed. The through-electrode 13 is not mentioned in FIG. 4. To form the back pattern 15, first of all, the overall surface of the back face 12 of the semiconductor substrate 10 is plated with Cu acting as the conductive substance (S410). Photo resist is then applied to the overall surface of the back face 12 (S411) to mask a portion intended to be the back pattern 15 through the exposure and development (S412).

Etching is then performed to remove Cu in portions other than the portion intended to be the back pattern 15 (S413). The photo resist is then removed (S414). The back pattern 15 is thus formed on the second face of the semiconductor substrate 10.

The front pattern 17 is then formed on the front face 11 of the semiconductor substrate 10. FIG. 5 shows a process flow upon forming of the front pattern 17. The through-electrode 13 is not mentioned in FIG. 5. To form the front pattern 17, first of all, the overall surface of the front face 11 of the semiconductor substrate 10 is plated with Cu acting as the conductive substance (S510). Photo resist is then applied to the front face 11 (S511) to mask a portion intended to form the front pattern 17 through the exposure and development (S512). Etching is then performed to remove Cu applied to portions other than the portion intended to form the front pattern 17 (S513). The photo resist is then removed (S514). The front pattern 17 is thus formed on the front face 11 of the semiconductor substrate 10.

The circuit element 16 is mounted on the semiconductor substrate 10 through the above process steps. If necessary, wiring step is applied via the wire bonding 19, etc., for electrically connecting the circuit element 16 and the semiconductor substrate 10. In case the circuit element 16 is provided that is configured by the back pattern 15 itself like the above-described spiral inductor, the circuit element 16 is formed during the forming process of the back pattern 15 as shown in FIG. 4.

After the above process steps, the solder resist 20 is further applied to the front face 11 as well as to the back face 12 of the semiconductor substrate 10. The solder bumps 18 are formed on top of the front face 11. Afterwards, dicing is performed into chips to complete the semiconductor substrate 10.

It is to be appreciated that the above description of the embodiment is merely for the purpose of facilitating the understanding of the present invention and is not intended to limit the scope of the present invention. Naturally, the present invention can variously be changed or modified without departing from the spirit thereof and encompasses the equivalents thereof.

For example, the thus configured semiconductor substrate 10 may have the through-electrode 13 formed after the completion of the electronic device 14 and the circuit element 16. More specifically, a silicon substrate is first subjected to a semiconductor fabrication process to form thereon the electronic device 14 of a single-layer structure or of a multi-layer structure, previous to the provision of the circuit element 16. The process shown in FIGS. 3A to 3H is then applied thereto to form the through-electrode 13 from the back face 12. In case of forming the through-electrode 13 after the provision of the electronic device 14 and the circuit element 16 in this manner, the insulating film 20 lying on the front face 11 for example is exposed at the bottom of the through-electrode 13.

### Semiconductor Apparatus (1) Having Conductive Pattern

<Separate Semiconductor Apparatus>

On the front side of the solder resist 20 of the semiconductor apparatus 1 (FIG. 2A), a dummy pattern (conductive pattern) 220 that will be described later may be disposed on a surface opposite to the circuit element 16 in the form of the spiral inductor (planar coil).

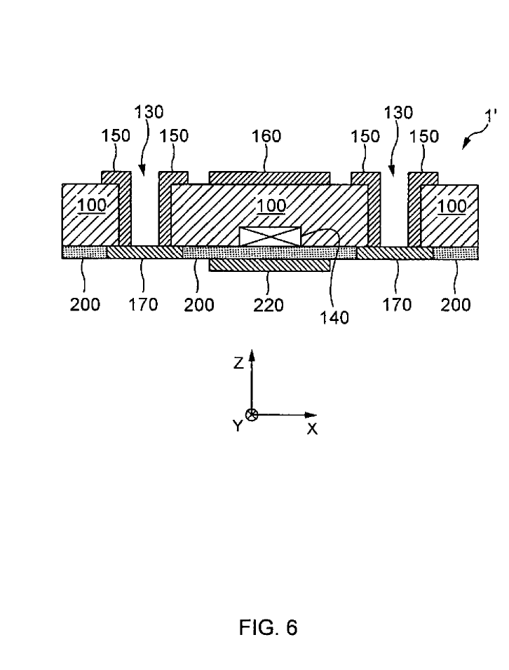

As exemplarily shown in the diagrammatic sectional view of FIG. 6, a semiconductor apparatus 1′ of this embodiment includes mainly a semiconductor substrate 100 having an electronic device 140 formed thereon, a through-electrode 130, a coil (inductor) 160, and a dummy pattern 220. The semiconductor substrate 100, the through-electrode 130, and the coil 160 have the same configurations as those of the semiconductor substrate 10, the through-electrode 13, and the circuit element 16, respectively, as exemplarily shown in FIG. 2A. Although not directly shown in FIG. 6, the coil 160 is electrically connected to the electronic device 140 by way of a back pattern 150, the through-electrode 130, and a front pattern 170. On the front side (−Z side) of the semiconductor substrate 100, solder resist (insulating material) 200 is disposed on portions other than the portions intended as bonding pads and has the same configuration as that of the solder resist 20 described above.

The dummy pattern 220 of this embodiment is disposed on the front side of the solder resist 200 such that the dummy pattern 220 is opposite to the coil 160 on the rear side (+z side) of the semiconductor substrate 100. Specifically, the dummy pattern 220 is made mainly of copper (Cu) and conforms in contour to the coil 160. In other words, the dummy pattern 220 has its periphery at a position conforming to or beyond the circumference of the coil 160. In case the coil 160 of this embodiment consists of a plurality of coils not shown arranged on the rear face of the semiconductor substrate 100, the dummy pattern 220 has a contour conforming to the general contour of the plurality of coils. This allows the dummy pattern 220 to absorb an electromagnetic field that may occur from the coil 160 in −Z direction upon action of the coil 160, as will be described later. The dummy pattern 220 of this embodiment may be in the form of rolled copper foil adhered to or copper plating formed on the front face of the solder resist 200. The main material of the dummy pattern 220 of this embodiment is not limited to copper, but may be for example gold, silver, tin, indium, aluminum, nickel, chrome, alloys thereof, etc.

Although in the semiconductor apparatus 1′ of FIG. 6 the electronic device 140 is formed on the inside (+Z side) of the front face of the semiconductor substrate 100 with the layer of the solder resist 200 confronting the front face of the electronic device 140 and with the conductive pattern 220 confronting the front face of the solder resist layer, the semiconductor apparatus 1′ may differently be configured. For example, the electronic device 140 may be formed at a position on the front face of the semiconductor substrate 100 offset in XY direction from the position opposite exactly to the inductor 160. The offset position may be a position P1 not shown where the electronic device 140 and the dummy pattern 220 do not overlap each other at all or may be a position P2 not shown where the electronic device 140 overlaps partly with the dummy pattern 220 in XY direction. In case of the position P1 in particular, the electronic device 140 may be formed further extending in −Z direction. In either case of the above, the solder resist 200 has only to be patterned such that the electronic device 140 and the dummy pattern 220 are electrically insulated from each other. In case of the electronic device 140 protruding in −Z direction at the position P1 in particular, the solder resist 200 and the dummy pattern 200 may be patterned such that they are for example juxtaposed with the electronic device 140 on the front face of the semiconductor substrate 100.

In the separate semiconductor apparatus 1′ of this embodiment, the dummy pattern 220 is a major conductive substance capable of being mutual inductance coupled with the coil 160. Thus, with the fabricator for example designing the dummy pattern 220 in advance such that the coil 160 of the separate semiconductor apparatus 1′ has a predetermined inductance characteristic, the predetermined inductance characteristic of the coil 160 can be kept as long as the user for example mounts the semiconductor apparatus 1′ away from dielectric substance, etc. Stably keeping the inductance characteristic of the coil 160 enables the degree of possible interference of the coil 160 with the electronic device 140 to be kept constant. Thus, according to the semiconductor apparatus 1′ of this embodiment, the mounting efficiency can be improved suppressing the interference of the coil 160 that may render the electronic device 140 unstable.

Similar to the case of the semiconductor apparatus 1 (FIG. 2B) described earlier, a buffer layer not shown similar to the buffer layer 21 (FIG. 2B) may be interposed between the semiconductor substrate 100 and the back pattern 150 due to a risk that the characteristic of the coil 160 may alter as a result of deformation of the semiconductor substrate 100 if the semiconductor substrate 100 is thin. This buffer layer can be of, for example, a material having a small specific resistance such as pure silicon (Si) with a view to improving the Q value or of a material with a low dielectric constant to improve the high-frequency characteristics. This buffer layer can also be a resin sheet, etc., to relieve the stress.

<Mounting onto Circuit Board>

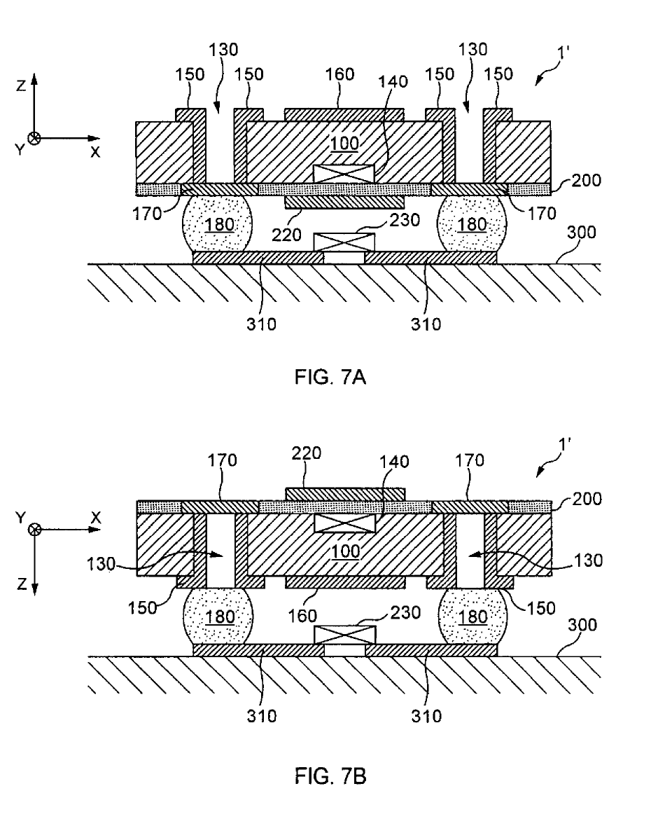

As exemplarily shown in a diagrammatic sectional view of FIG. 7A, the above semiconductor apparatus 1′ is able to be mounted via e.g., solder bumps 180 onto a circuit substrate 300 of, e.g., a hand-held equipment. In the exemplary representation of FIG. 7A, a front pattern 170 of the semiconductor apparatus 1′ is electrically connected via the solder bumps 180 to a conductive path (electrode) 310 formed on a circuit substrate 300. On the other hand, FIG. 7A exemplarily shows a semiconductor component 230 mounted together with the semiconductor apparatus 1′ onto the circuit substrate 300, the semiconductor apparatus 1′ being positioned such that a dummy pattern 220 thereof confronts the semiconductor component 230. Although in the exemplary representation of FIG. 7A the semiconductor component 230 is electrically connected to the semiconductor apparatus 1′ by way of the conductive path 310 and the solder bumps 180, this is not intended to be limitative and instead the semiconductor component 230 may be an element that is electrically independent of the semiconductor apparatus 1′. The semiconductor element 230 can also be the active element or integrated circuit of MOS structure, or a passive element such as the resistor, inductor and capacitor.

By virtue of the above configuration allowing the dummy pattern 220 to absorb an electromagnetic field that may occur as a result of action of the coil 160, electromagnetic interference can be suppressed onto the semiconductor component 230, etc., on the circuit substrate 300 to be mounted with the semiconductor apparatus 1′ of this embodiment. Silicon for example, a major material of the semiconductor substrate 100 has a higher dielectric constant than that of atmosphere (air) for example and hence is able to effectively absorb and confine the electromagnetic filed leaking out of the coil 160 in cooperation with the dummy pattern 220. Due to the semiconductor apparatus 1′ capable of being mounted such that the semiconductor component 230 lies between the semiconductor apparatus 1′ and the circuit substrate 300, the mounting efficiency is improved on the circuit substrate 300.

As exemplarily shown in a diagrammatic sectional view of FIG. 7B, the above semiconductor apparatus 1′ is able to be mounted onto the circuit substrate 300 by way of the solder bumps 180. In the exemplary representation of FIG. 7B, a back pattern 150 of the semiconductor apparatus 1′ is electrically connected via the solder bumps 180 to the conductive path 310 formed on the circuit substrate 300. On the other hand, FIG. 7B exemplarily shows the circuit substrate 300 mounted with the semiconductor component 230 together with the semiconductor apparatus 1′, the semiconductor apparatus 1′ being positioned such that a coil 160 thereof confronts the semiconductor component 230. Although in the exemplary representation of FIG. 7B the semiconductor component 230 is electrically connected to the semiconductor apparatus 1′ by way of the conductive path 310 and the solder bumps 180, this is not intended to be limitative and instead the semiconductor component 230 may be an element that is electrically independent of the semiconductor apparatus 1′.

The above configuration allows the dummy pattern 220 to stabilize the inductance characteristic of the coil 160, to thereby keep constant the degree of interference of the coil 160 with the semiconductor component 230. Thus, according to the semiconductor apparatus 1′ of this embodiment, the mounting efficiency can be improved suppressing the interference of the coil 160 that may render the semiconductor component 230 unstable.

Although in the above embodiment the semiconductor apparatus 1′ is mounted via the solder bumps 180 onto the circuit board 300, this is not intended to be limitative. For example, the semiconductor apparatus 1′ and the circuit board 300 may be electrically connected Lo each other via wire bonding. It is however to be appreciated that use of the solder bumps 180 ensures a further improvement in the mounting efficiency.

### Semiconductor Apparatus (2) Having Conductive Pattern

A dummy pattern (conductive pattern) 420 that will be described hereinbelow may be disposed on the back side of the semiconductor apparatus 1 (FIG. 2A) such that the dummy pattern 420 confronts the spiral inductor (planar coil) acting as the circuit element 16.

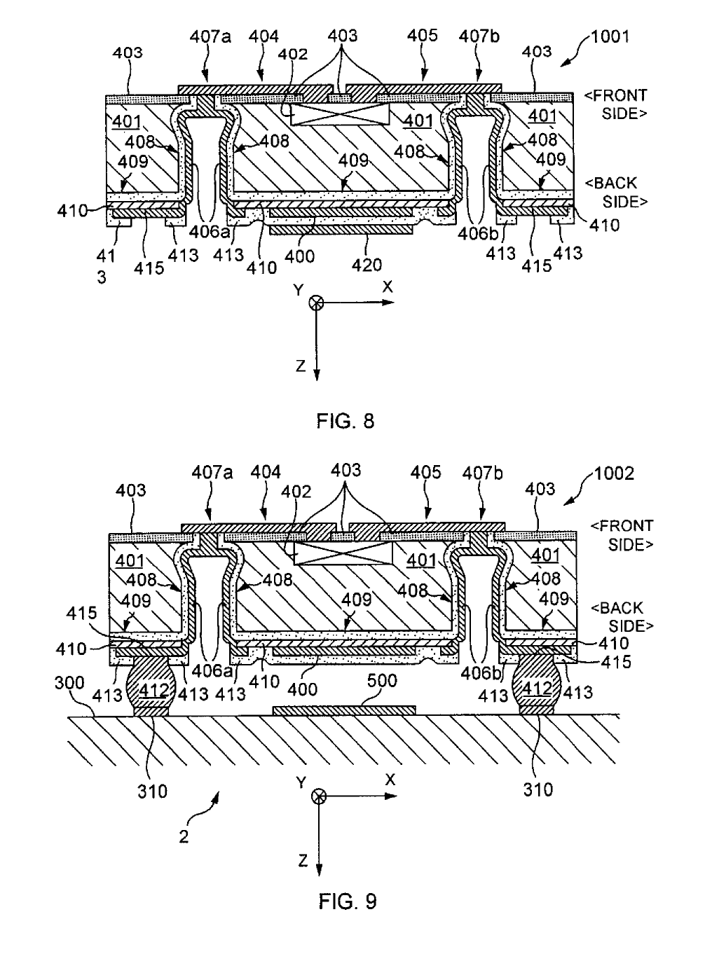

As exemplarily shown in a diagrammatic sectional view of FIG. 8, a semiconductor apparatus 1001 of this embodiment is comprised mainly of a semiconductor substrate 401 in the form of a chip on which an element (electronic device) 402 is formed, through-electrodes 406a and 406b, a coil (inductor) 400, and a dummy pattern 420. The semiconductor substrate 401, the through-electrodes 406a and 406b, and the coil 400 are provided respectively with similar configurations to respective ones of the semiconductor substrate 10, the through-electrode 13, and the circuit element 16 of the semiconductor apparatus 1 exemplarily shown in FIG. 2A and are fabricated by a fabrication process that will be described later.

P-type and N-type diffused regions are formed on the front face (surface on −Z side) of the semiconductor substrate 401 of this embodiment, with the surface defining a discrete circuit or an integrated circuit (IC) on which at least one element (electronic device) 402 is formed. In case this surface defining a discrete transistor for example, an emitter electrode 404 and a base electrode 405 are formed by way of insulating layers 403 and extend via rewiring to regions where the through-electrodes 406a and 406b are formed, respectively, to terminate at contact electrodes 407a and 407b, respectively, that are in contact with the through-electrodes 406a and 406b, respectively.

The semiconductor substrate 401 of this embodiment has through-regions extending from the back face (surface on +Z side) thereof to the contact electrodes 407a and 407b, with insulating layers 408 being formed on the inner walls of the through-regions. To provide electrical insulation from the back face of the semiconductor substrate 401 made of silicon (Si), the coil 400 is disposed via a silicon oxide film (SiO₂) 409 on top of the back face. An insulating resin (buffer layer) 410 with a flexibility is formed at a boundary between the coil 400 and the semiconductor substrate 401 to reduce stresses that may occur at the boundary due to the difference in thermal expansion coefficient therebetween.

The through-electrodes 406a and 406b of this embodiment are formed from the back face of the semiconductor substrate 401 to the inner walls of the through-regions and electrically connect to the contact electrodes 407a and 407b, respectively, at the front face of the semiconductor substrate 401. The coil 400 may be formed simultaneously with the formation of the through-electrodes 406a and 406b or may separately be formed.

The above configuration allows the electrodes 404 and 405 electrically connected to the element 402 formed in the active region on the front face of the semiconductor substrate 401 to connect to the rewiring, contact electrodes 407a and 407b, through-electrodes 406a and 406b, and the electrode 415 on the back face of the semiconductor substrate 401.

Solder resist (insulating material) 413 is formed on the back face of the semiconductor substrate 401 of this embodiment to form e.g., solder bumps (or solder balls) 412 (FIG. 9) thereon. The coil 400 is thereby coated with the solder resist 413. This coil 400 electrically connects to one electrode on the front face of the semiconductor substrate 401 by way of through-electrodes not shown. In case of the coil 400 disposed on the back face of an IC for example, the coil 400 is connected to one electrode of the IC.

It is to be noted that the semiconductor apparatus 1001 of this embodiment may be provided with the solder bumps (or solder balls) 412 or instead that the solder bumps (or solder balls) 412 may be provided on a circuit substrate to be mounted with the semiconductor apparatus 1001.

The dummy pattern 420 of this embodiment is disposed on +Z side of the solder resist 413 such that the dummy pattern 420 confronts the coil 400 via the solder resist 413. Specifically, the dummy pattern 420 is made mainly of copper (Cu) for example and conforms in contour to the coil 400. In other words, this dummy pattern 420 has its periphery at a position conforming to or beyond the circumference of the coil 400. In case the coil 400 of this embodiment consists of a plurality of coils not shown arranged and connected to each other on the back face of the semiconductor substrate 401 for example, this dummy pattern 420 is so shaped as to conform to the general contour of the plurality of coils. The dummy pattern 420 of this embodiment may be rolled copper foil adhered to the front face of the solder resist 413 or it may be formed by copper plating. The main material of the dummy pattern 420 of this embodiment is not intended to be limited to copper, but instead can be e.g., copper, gold, silver, tin, indium, aluminum, nickel, chrome or alloys thereof.

In the semiconductor apparatus 1001 of this embodiment, the major conductive substance capable of mutual inductance coupling with the coil 400 is the dummy pattern 420 formed confronting the coil 400 via the solder resist 413 disposed therebetween. Thus, by designing in advance the dummy pattern 420 so that the coil 400 has a predetermined inductance characteristic in the separate semiconductor apparatus 1001, the predetermined inductance of the coil 400 can be kept. According to this semiconductor apparatus 1001, magnetic lines of force in +Z direction are blocked by silicon (Si) forming the semiconductor substrate 401 whereas magnetic lines of force in −Z direction are blocked by the dummy pattern 420. Although typically, the magnetic fields (magnetic lines of force) may possibly change the inductance value of the coil 400 to a large extent through electromagnetic induction, these blocks prevent magnetic fields from occurring in the vicinity of the coil 400 (i.e., prevent the magnetic lines of force from reaching the coil 400), thereby allowing the coil 400 to keep its predetermined inductance value. Stable keeping of the inductance value enables the degree of interference of the coil 400 with the element 402 for example to be kept constant. The mounting efficiency can thus be enhanced while suppressing the interference of the coil 400 that may render the element 402 unstable.

### Semiconductor Module Having Conductive Pattern

When the semiconductor apparatus 1 (FIG. 2A) is mounted on the circuit board 300 (FIG. 7A), the mounting may be carried out such that the spiral inductor (planar coil) acting as the circuit element 16 confronts a dummy pattern (conductive pattern) 500 (FIG. 9) on the circuit board (mounting board) 300.

As exemplarily shown in a diagrammatic sectional view of FIG. 9, a semiconductor module of this embodiment is generally designated at 2 and includes a semiconductor apparatus generally designated at 1002, and the circuit board 300 having a dummy pattern 500 thereon. The semiconductor apparatus 1002 is comprised mainly of the semiconductor substrate 401 in the form of a chip having the element (electronic device) 402 formed thereon, the through-electrodes 406a and 406b, and the coil (inductor) 400. The semiconductor apparatus 1002 is configured such that the position of formation of the coil 400 confronts the position of formation of the dummy pattern 500 when mounted on the circuit board 300. It is to be noted that the semiconductor apparatus 1002 of this embodiment has substantially the same configuration as that of the semiconductor apparatus 1001 exemplarily shown in FIG. 8, except that the former is not provided with the dummy pattern 420 of FIG. 8. The electrode 415 on the back face (surface on +Z side) of the semiconductor apparatus 1002 of this embodiment is electrically connected to the conductive path 310 formed on the circuit board 300 by way of the solder bumps (solder balls) 412.

In the semiconductor module 2 of this embodiment, the major conductive substance capable of mutual inductance coupling with the coil 400 is the dummy pattern 500 formed at a position confronting the position where the coil 400 is formed on the circuit board 300. Thus, by designing the dummy pattern 500 so that the coil 400 has a predetermined inductance characteristic when the semiconductor apparatus 1002 is mounted on the circuit board 300, the predetermined inductance of the coil 400 can be kept. According to the semiconductor module 2 of this embodiment, magnetic lines of force in +Z direction are blocked by the semiconductor substrate 401 whereas magnetic lines of force in −Z direction are blocked by the dummy pattern 500, allowing the coil 400 to keep its predetermined inductance characteristic. Stable keeping of the inductance value enables the degree of interference of the coil 400 with the element 402 for example to be kept constant. The mounting efficiency can thus be enhanced while suppressing the interference of the coil 400 that may render the element 402 unstable.

### Method of Fabricating Semiconductor Apparatus

Description will be made of a method of fabricating the semiconductor apparatuses 1001 and 1002 having the above configurations. In the following description, a silicon substrate is used as the semiconductor substrate 401. The base wafer is a 130 μm thick silicon wafer having, on its front face and back face, 5 μm thick insulating layers 155″ and 156″, respectively, of silicon oxide film (SiO₂) applied by thermal oxidation method, plasma CVD (Chemical Vapor Deposition), sputtering, etc. The front face of the semiconductor substrate 401 has thereon an electronic device such as an active element or integrated circuit of MOS (Metal Oxide Semiconductor) structure or of BIP (Bipolar) structure, formed by a pre-step such as thermal oxidation method, CVD (Chemical Vapor Deposition), sputtering, lithography or impurity diffusion.

<Through-Electrode>

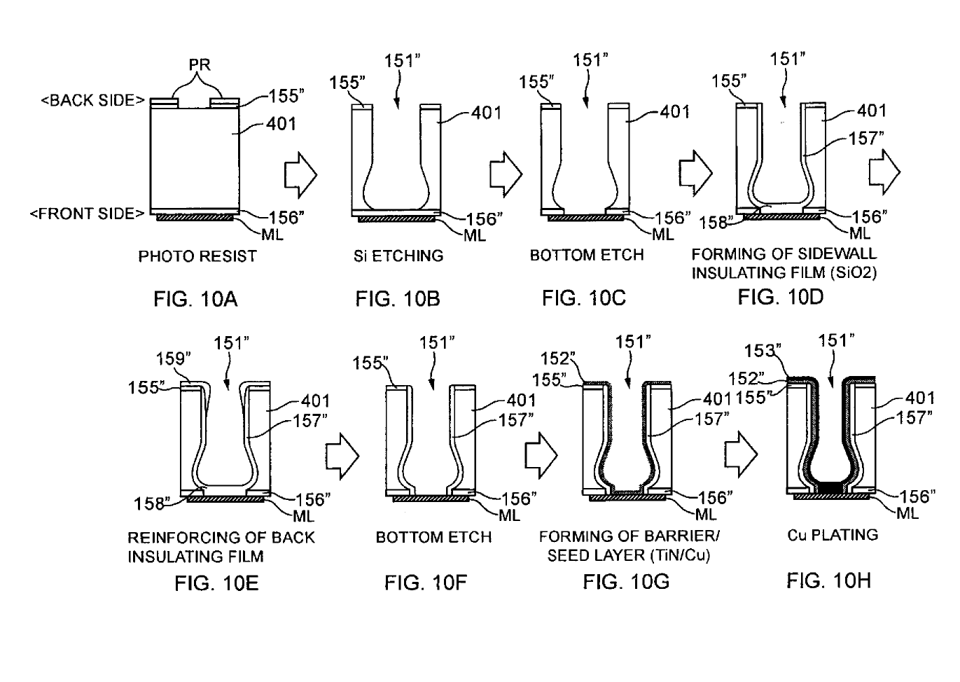

FIG. 10 shows the process of forming the through-electrodes (e.g., through-electrodes 406a and 406b) in the semiconductor substrate 401. As described earlier, the insulating layer 155″ in the form of a silicon oxide film (SiO₂), an insulating resin film, etc., is formed on the back face (surface opposite to the front face formed by diffusion) of the semiconductor substrate 401. To form the through-electrodes, photo resist (PR) is first applied to portions of this back face other than portions (40 μm dia.) where the through-electrodes are to be formed, after which etching is performed using an etching gas such as carbon tetrafluoride (CF₄) to remove the insulating layer 155″ lying on the portions where the through-electrodes are to be formed. FIG. 10A shows the status after the removal of the insulating layer 155″ lying on the portions where the through-electrodes are to be formed. An electrode ML is an electrode or wire made of metal materials. For example, the electrode ML is made of Al, Cu, etc., or consists of layers of Ti—TiN—Al laid in the mentioned order from the underlayer.

Etching is then performed using an etching gas such as carbon hexafluoride (CF₆) to form a through-hole 151″ in the semiconductor substrate 401 (FIG. 10B). As a result of this, the insulating layer 156″ is exposed at the bottom of the through-hole 151″. In this case, the silicon oxide film for example of the insulating layer 156″ and silicon of the semiconductor substrate 401 have different etching rates, and therefore, in the exemplary representation of FIG. 10B, the etched regions are laterally extended toward the insulating layer 156″ due to over-etching.

Etching is then performed using an etching gas such as carbon tetrafluoride (CF₄) to remove the portion of the insulating layer 156 exposed at the bottom of the through-hole 151″ (FIG. 10C). The electrode ML becomes thus exposed at the bottom.

To insulate a silicon surface exposed on an inner peripheral surface of the through-hole 151″, an SiO₂ insulating film 157″ is then formed on the inner peripheral surface of the through-hole 151″ by CVD, thermal oxidation method, sputtering, etc (FIG. 10D). It is to be noted that execution of this step allows SiO₂ 158″ to again adhere to the bottom of the through-hole 151″.

SiO₂ 158″ adhering to the bottom of the through-hole 151″ is then removed. At that time, to prevent the insulating film 157″ of the through-hole 151″ formed near the surface from peeling off, a protection film 159″ is formed in advance on the insulating film 157″ of the through-hole 151″ near the surface by CVD, thermal oxidation method, sputtering, etc (FIG. 10E). It is to be noted that the formation of this protection film 159″ is not essential, i.e., may not be performed.

Anisotropic etching is then applied from the back face. This removes SiO₂ 158″ lying at the bottom of the through-hole 151″. Due to the anisotropic etching allowing the bottom to be more etched than the sidewalls, the insulating layer 156″ can be etched so as to have an opening of substantially the same size as that of the opening of the through-hole 151″. Thus, previous formation of the protection film 159″ at the opening of the through-hole 151″ allows a smaller opening, reduced with this protection film 159″, than in regions toward the insulating layer 156″ to be formed inside thereof.

A barrier layer 152″ consisting of TiN or Ti and TiN laid in the mentioned order from the underlayer is then formed on the inner peripheral surface of the through-hole 151″ by CVD (FIG. 10G). The barrier layer 152″ may be made of other metals as long as it functions as a barrier layer.

A conductive layer is then formed thereon using a film formation method such as CVD method or electroless plating. In other words, the surface of the barrier layer 152″ is plated with a conductive substance 153″ (FIG. 10H). By way of the execution of the above steps, the through-electrodes (e.g., through-electrodes 406a and 406b) are formed in the semiconductor substrate 401.

<Back Pattern>

The back pattern (e.g., electrode 415) is then formed on the back face of the semiconductor substrate 401 having the through-electrodes thus formed therein. The process flow for formation of the back pattern is substantially the same as that of FIG. 4, and hence will be described with reference to FIG. 4.

To form the back pattern, first of all, the overall surface of the back face of the semiconductor substrate 401 is plated with Cu acting as the conductive substance as described above in FIG. 10H (S410). Photo resist is then applied to the overall surface of the back face (S411) to mask a portion intended to be the back pattern through the exposure and development (S412). Etching is then performed to remove Cu and the barrier layer 152″ in portions other than the portion intended to be the hack pattern (S413). The photo resist is then removed (S414). The back pattern is thus formed on the back face of the semiconductor substrate 401. In case of formation of the solder bumps (solder balls) 412 on the back face as exemplarily shown in FIG. 9, solder resist 413 for example is formed on the back pattern except for regions in contact with the solder bumps (solder balls) 412, the solder bumps (solder balls) 412 etc., being formed at the opening of the solder resist 413. A barrier of Ni, etc., may intervene between the solder bumps (or solder balls) 412 and Cu of the electrode 415. In case of the semiconductor apparatus 1001 exemplarily shown in FIG. 8, the coil 400 may be formed simultaneously with the formation of the through-electrodes 406a and 406b or may separately be formed as described hereinabove.

<Front Pattern>

The front patterns (e.g., electrodes 404 and 405) are then formed on the front face of the semiconductor substrate 401. The process flow for formation of the front pattern is substantially the same as that of FIG. 5, and hence will be described with reference to FIG. 5.

To form the front pattern, first of all, the overall surface of the front face of the semiconductor substrate 401 is plated with Cu acting as the conductive substance (S510). It is natural that plural layers of electrodes and wirings are formed via insulating layers on top of the semiconductor substrate 401 to form an ordinary discrete device or LSI device. On top thereof is formed an insulating layer of, e.g., insulating resin or SiN, via which Cu electrically connecting to a desired electrode is formed on the overall surface. Photo resist is applied to the front face (S511) to mask a portion intended to form the front pattern through the exposure and development (S512). Etching is then performed to remove Cu applied to portions other than the portion intended to form the front pattern (S513). The photo resist is then removed (S514). The front pattern is thus formed on the front face of the semiconductor substrate 401.

A circuit element not shown similar to the circuit element 16 is mounted on the semiconductor substrate 401 through the above process steps. If necessary, wiring step is applied via the wire bonding not shown for electrically connecting the circuit element 16 and the semiconductor substrate 401 to each other. In case of the circuit element in the form of the coil 400, such a circuit element is formed through a process similar to the process of forming the back pattern exemplarily shown in FIG. 10.

After the above process steps, a solder resist not shown is further applied to the front face of the semiconductor substrate 401. The solder bumps (solder balls) 412 may be formed on top of the front face. Afterwards, dicing is performed into chips to complete the semiconductor substrates 1001 and 1002.

It is to be appreciated that the above description of the embodiment is merely for the purpose of facilitating the understanding of the present invention and is not intended to limit the scope of the present invention. Naturally, the present invention can variously be changed or modified without departing from the spirit thereof and encompasses the equivalents thereof.

Although the above circuit elements 16 and 160 are passive elements such as resistors, inductors and capacitors, they are not intended to be limitative and can be e.g., crystal oscillators.

Although in the above embodiments the semiconductor apparatuses 1001 and 1002 are mounted via the solder bumps 412 onto the circuit board 300, this is not intended to be limitative. For example, electrical connection may be provided via wire bonding between the semiconductor apparatuses 1001 and 1002 and the circuit board 300. It is however to be noted that use of the solder bumps 412 ensures more improvement in the mounting efficiency.

While the exemplary embodiments of the present invention have been described hereinabove, it will be appreciated that the above embodiments are merely for the purpose of facilitating the understanding of the present invention and are not intended to construe the present invention as being limitative. Naturally, the present invention can variously be changed or modified without departing from the spirit thereof and encompasses the equivalents thereof.

What is claimed is:

1. A semiconductor apparatus comprising:
a semiconductor substrate having a front face and a back face, the front face having an electronic device formed thereon;
a through-electrode extending through the semiconductor substrate;
a solder bump disposed on the front side of the semiconductor substrate, the solder bump connecting to the through-electrode; and
a circuit element disposed on the back side of the semiconductor substrate, the circuit element connecting via the through-electrode to the electronic device.

2. The semiconductor apparatus of claim 1, wherein the circuit element is an inductor or a capacitance element.

3. The semiconductor apparatus of claim 1, wherein the circuit element is configured by a wiring pattern itself formed on the back side of the semiconductor substrate.

4. The semiconductor apparatus of claim 3, wherein a buffer layer is formed between the back face and the circuit element.

5. The semiconductor apparatus of claim 4, wherein the buffer layer is made of pure silicon.

6. The semiconductor apparatus of claim 1, wherein the semiconductor substrate is a silicon substrate.

7. A semiconductor apparatus comprising:
a semiconductor substrate having a front side and a back side, the front side having an electronic device formed thereon;
an inductor formed on the back side of the semiconductor substrate;
a through-electrode extending through the semiconductor substrate from a front face to a back face thereof, the through-electrode electrically connecting the electronic device and the inductor; and
a conductive pattern formed at a position on the front side of the semiconductor substrate opposite to a position where the inductor is formed on the back side of the semiconductor substrate, the conductive pattern stabilizing inductance of the inductor.

8. The semiconductor apparatus of claim 7, wherein the conductive pattern is connected via an insulating material to the front face of the semiconductor substrate.

9. The semiconductor apparatus of claim 8, wherein the conductive pattern on the front side of the semiconductor substrate confronts a semiconductor component on a circuit board, and wherein the through-electrode is connected via a solder bump to an electrode on the circuit board.

10. The semiconductor apparatus of claim 8, wherein the inductor on the back side of the semiconductor substrate confronts a semiconductor component on a circuit board, and wherein the through-electrode is connected via a solder bump to an electrode on the circuit board.

11. A semiconductor apparatus comprising:
a semiconductor substrate having a front side and a back side, the front side having an electronic device formed thereon;
an inductor formed on the back side of the semiconductor substrate;
a through-electrode extending through the semiconductor substrate from a front face to a back face thereof, the through-electrode electrically connecting the electronic device and the inductor; and
a conductive pattern formed via an insulating material at a position confronting a position where the inductor is formed on the back side of the semiconductor substrate, the conductive pattern stabilizing inductance of the inductor.

12. The semiconductor apparatus of claim 11, wherein the semiconductor substrate is made of a material blocking magnetic lines of force from the front side toward the back side of the semiconductor substrate, and wherein the conductive pattern is made of a material blocking magnetic lines of force from the back side toward the front side of the semiconductor substrate.

13. The semiconductor apparatus of claim 11, comprising a buffer layer formed between the back face of the semiconductor substrate and the inductor, the buffer layer reducing stresses that occur between the back face of the semiconductor substrate and the inductor.

14. A semiconductor module comprising:
a semiconductor apparatus, the semiconductor apparatus including a semiconductor substrate having a front side and a back side, the front side having an electronic device formed thereon; an inductor formed on the back side of the semiconductor substrate; and a through-electrode extending through the semiconductor substrate from a front face to a back face thereof, the through-electrode electrically connecting the electronic device and the inductor; and
a mounting substrate mounted with the semiconductor apparatus, the mounting substrate having thereon a conductive pattern formed at a position confronting a position where the inductor is formed on the back side of the semiconductor substrate, the conductive pattern stabilizing inductance of the inductor.

15. The semiconductor module of claim 14, wherein the semiconductor substrate is made of a material blocking magnetic lines of force from the front side toward the back side of the semiconductor substrate, and wherein the conductive pattern is made of a material blocking magnetic lines of force from the back side toward the front side of the semiconductor substrate.

16. The semiconductor module of claim 14, comprising a buffer layer formed between the back face of the semiconductor substrate and the inductor, the buffer layer reducing stresses that occur between the back face of the semiconductor substrate and the inductor.
